(19) United States
(12) Patent Application Publication
(10) Pub. No.: US 2016/0025908 A1
(43) Pub. Date: Jan. 28, 2016

(54) FLEXIBLE COLOR FILTER AND METHOD FOR MANUFACTRING THE SAME, DISPLAY DEVICE

(71) Applicant: BOE TECHNOLOGY GOUP CO., LTD., Beijing (CN)

(72) Inventors: SHAN CHANG, BEIJING (CN); ZHUO ZHANG, BEIJING (CN); CHUNYAN XIE, BEIJING (CN); WEI DENG, BEIJING (CN)

(73) Assignee: BOE TECHNOLOGY GOUP CO., LTD., BEIJING (CN)

(21) Appl. No.: 14/426,622

(22) PCT Filed: Apr. 10, 2014
(86) PCT No.: PCT/CN2014/075098

§ 371 Date: Mar. 6, 2015

(30) Foreign Application Priority Data
Dec. 25, 2013 (CN) 201310727325.5

(51) Int. Cl. G02B 5/22; G02B 1/14; G03F 7/00; G02B 5/20

(52) U.S. Cl. CPC G02B 5/22; G02B 5/201; G02B 1/14; G03F 7/0007

(57) ABSTRACT

Provided are a flexible color filter and a method for manufacturing the same. The flexible color filter includes a flexible substrate and a plurality of pixel structures formed on the flexible substrate, each pixel structure is covered with a protective layer for preventing the corresponding pixel structure from being deformed.

### TECHNICAL FIELD

The present disclosure relates to the field of flexible liquid crystal display technology, in particular to a flexible color filter and a method for manufacturing the same, as well as a display device.

### BACKGROUND

A color filter, being as an important device in LCD (Liquid Crystal Display) and WOLED (White Organic Light Emitting Diode), inevitably plays a vital role in a Next-Generation flexible display. However, during achieving the flexible display, all devices are bound to suffer extruding and stretching to some extent. For the color filter, when the pixel area suffers extruding or stretching, a thickness of a pixel film changes, which results in non-uniform color and influences display effect. In addition, repeated extrusion and stretching greatly shorten a service life of the devices.

### SUMMARY

In order to solve the above technical problem, the present disclosure provides a flexible color filter and a method for manufacturing the same, so as to guarantee a pixel structure being integral and being not deformed, thereby to prevent the color uniformity from being adversely influenced when the color filter is bent.

For achieving the above object, an embodiment of the present disclosure provides a flexible color filter, including a flexible substrate and a plurality of pixel structures formed on the flexible substrate, wherein each pixel structure is covered with a protective layer for preventing the corresponding pixel structure from being deformed.

Alternatively, a first face of the pixel structure away from the flexible substrate is covered with the protective layer.

Alternatively, the first face of the pixel structure away from the flexible substrate and side faces adjacent to the first face are covered with the protective layer.

Alternatively, the protective layer is made of a colorless transparent photosensitive resin.

Alternatively, the protective layer is a hard film formed on the pixel structure by a patterning process.

The present disclosure also provides a method for manufacturing a flexible color filter, including the following steps:

forming a plurality of pixel structures on a flexible substrate by a patterning process; and

foaming a protective layer on the pixel structure by a patterning process so as to prevent the corresponding pixel structure from being deformed.

Alternatively, the step of forming the protective layer on the pixel structure by the patterning process so as to prevent the corresponding pixel structure from being deformed further includes:

forming the protective layer on a first face of the pixel structure away from the flexible substrate by a patterning process.

Alternatively, the step of forming the protective layer on the pixel structure by the patterning process so as to prevent the corresponding pixel structure from being deformed further includes:

forming the protective layer on a first face of the pixel structure away from the flexible substrate and side faces adjacent to the first face by a patterning process.

Alternatively, the protective layer is made of a colorless transparent photosensitive resin.

Alternatively, the protective layer is a hard film formed on the pixel structure by a patterning process.

An embodiment of the present disclosure further provides a display device, including the above flexible color filter.

The present disclosure has the following advantageous effects. The protective layer is provided so that the pixel structure is not deformed when the flexible substrate is bent, thus a phenomenon of non-uniform color is avoided, and a service life of the color filter is prolonged.

### BRIEF DESCRIPTION OF THE DRAWINGS

FIG. 1 is a schematic diagram showing a structure of a flexible color filter according to an embodiment of the present disclosure;

FIG. 2 is a schematic diagram showing a pixel structure according to an embodiment of the present disclosure;

FIG. 3 is a schematic diagram showing a pixel structure according to another embodiment of the present disclosure; and

FIG. 4 is a schematic diagram showing a bent flexible color filter according to an embodiment of the present disclosure.

### DETAILED DESCRIPTION

The features and principles of the present disclosure are described in details in conjunction with following drawings. The embodiments below are only for illustrating the present disclosure, but not intended to limit the protection scope of the present disclosure.

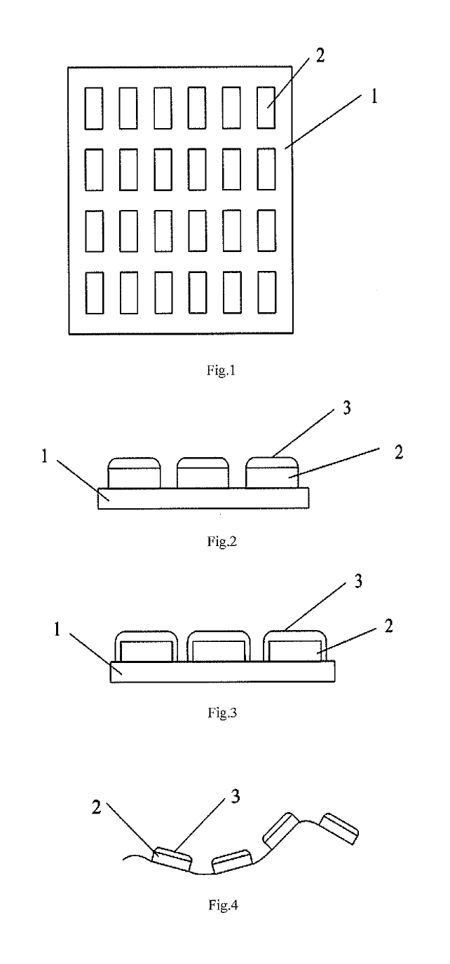

As shown in FIG. 1 to FIG. 4, the present embodiment provides a flexible color filter, which includes a flexible substrate 1 and a plurality of pixel structures 2 formed on the flexible substrate I, in which the pixel structure 2 is covered with a protective layer 3 for preventing the corresponding pixel structure from being deformed.

The flexible color filter is bent under a combined action of the flexible substrate 1 and the protective layer 3, the protective layer 3 is provided so that the pixel structure 2 is not deformed when the flexible substrate 1 is bent, thus a phenomenon of non-uniform color is avoided, and the service life of the color filter is prolonged.

In the present embodiment, the protective layer 3 is made of a colorless transparent photosensitive resin, for preventing the pixel structure 2 from being deformed while not influencing the function of the pixel structure 2.

The above effects can be achieved as long as the pixel structure 2 is not deformed and a radius of curvature of the whole bent flexible color filter is not influenced when the flexible substrate 1 is bent. Thus, there may be several structure forms of the protective layer 3. In the present disclosure, the protective layer 3 has a structure form below.

In an embodiment, a first face of the pixel structure 2 away from the flexible substrate 1 is fully covered with the protective layer 3.

The protective layer 3 is a hard film formed on the pixel structure 2 by a patterning process.

A process of forming the hard film is shown as below:

By means of the existing flexible display technology, the pixel structure 2 is obtained by evaporation/mask plate exposure, development on the flexible substrate 1.

A colorless transparent hard photosensitive resin is coated on a first face of the pixel structure 2 away from the flexible substrate 1, after being exposed and developed by a mask plate, a layer of transparent hard film is attached to the first face of the pixel structure 2.

The hard film is formed so that the pixel structure 2 is still maintained in a flat state even when the flexible substrate 1 is bent. Therefore, the phenomenon of non-uniform color during bending is avoided, and the service life of the flexible color filter is prolonged.

In order to prevent the pixel structure 2 from being deformed more effectively, in an embodiment, a hard material is used for packaging the pixel structure 2, so as not to influence a soft connection between the pixel structure 2 and the flexible substrate 1, and a radius of curvature of the bent flexible substrate 1 while protecting a pixel area. Thus, the pixel structure 2 may have a package structure form shown as below.

In an embodiment, both the first face of the pixel structure 2 away from the flexible substrate 1 and side faces adjacent to the first face are covered with the protective layer 3.

A package shell is formed with the protective layer 3, which is fully covered on the first face and the side faces adjacent to the first face so as to package the pixel structure 2.

A process of forming the packaging shell is shown below.

By means of the existing flexible display technology, the pixel structure 2 is obtained by evaporation/mask plate exposure, development on the flexible substrate 1.

The pixel structure 2 is packaged using a hard package material (colorless transparent hard photosensitive resin composition), so that the pixel structure 2 is flat without being deformed, and the bent integral structure is not influenced.

Packaging steps include coating the colorless transparent hard photosensitive resin composition on the obtained pixel structure 2, after being exposed and developed by a mask plate, attaching a layer of transparent hard film to the first face of the pixel structure 2 and the side faces adjacent to the first face.

The present disclosure also provides a method for manufacturing a color filter, which includes the following steps of:

forming a plurality of pixel structures on a flexible substrate by a patterning process; and

forming a protective layer on the pixel structure by a patterning process so as to prevent the corresponding pixel structure from being deformed.

In an embodiment, the step of forming the protective layer on the pixel structure by the patterning process so as to prevent the corresponding pixel structure from being deformed further includes:

forming the protective layer on the first face of the pixel structure away from the flexible substrate by a patterning process.

In an embodiment, the step of forming the protective layer on the pixel structure by the patterning process so as to prevent the corresponding pixel structure from being deformed further includes:

forming the protective layer on the first face of the pixel structure away from the flexible substrate and side faces adjacent to the first face by a patterning process.

Alternatively, the protective layer is made of a colorless transparent hard photosensitive resin composition.

The above color filter according to embodiments of the present disclosure may be applied to a display device.

The above are merely the preferred embodiments of the present disclosure. It should be noted that, a person skilled in the art may further make improvements and modifications without departing from the principle of the present disclosure, and these improvements and modifications shall also be considered as the scope of the present disclosure.

1. A flexible color filter, comprising a flexible substrate and a plurality of pixel structures formed on the flexible substrate, wherein each pixel structure is covered with a protective layer for preventing the corresponding pixel structure from being deformed.

2. The flexible color filter according to claim 1, wherein a first face of the pixel structure away from the flexible substrate is covered with the protective layer.

3. The flexible color filter according to claim 1, wherein a first face of the pixel structure away from the flexible substrate and side faces adjacent to the first face are covered with the protective layer.

4. The flexible color filter according to any one of claims 1 to 3 claim 1, wherein the protective layer is made of a colorless transparent photosensitive resin.

5. The flexible color filter according to any one of claims 1 to 4 claim 1, wherein the protective layer is a hard film formed on the pixel structure by a patterning process.

6. A method for manufacturing a flexible color filter, comprising the following steps:
forming a plurality of pixel structures on a flexible substrate by a patterning process;
forming a protective layer on the pixel structure by a patterning process so as to prevent the corresponding pixel structure from being deformed.

7. The method according to claim 6, wherein the step of forming the protective layer on the pixel structure by the patterning process so as to prevent the corresponding pixel structure from being deformed further comprises:
forming the protective layer on a first face of the pixel structure away from the flexible substrate by a patterning process.

8. The method according to claim 6, wherein the step of forming the protective layer on the pixel structure by the patterning process so as to prevent the corresponding pixel structure from being deformed further comprises:
forming the protective layer on a first face of the pixel structure away from the flexible substrate and side faces adjacent to the first face by a patterning process.

9. The method according to claim 6, wherein the protective layer is made of a colorless transparent photosensitive resin.

10. The method according to claim 6, wherein the protective layer is a hard film formed on the pixel structure by a patterning process.

11. A display device, comprising a flexible color filter according to claim 1.

12. The flexible color filter according to claim 2, wherein the protective layer is made of a colorless transparent photosensitive resin.

13. The flexible color filter according to claim 3, wherein the protective layer is made of a colorless transparent photosensitive resin.

14. The flexible color filter according to claim 2, wherein the protective layer is a hard film formed on the pixel structure by a patterning process.

15. The flexible color filter according to claim 3, wherein the protective layer is a hard film formed on the pixel structure by a patterning process.

16. The flexible color filter according to claim 4, wherein the protective layer is a hard film formed on the pixel structure by a patterning process.

17. The method according to claim 7, wherein the protective layer is made of a colorless transparent photosensitive resin.

18. The method according to claim 8, wherein the protective layer is made of a colorless transparent photosensitive resin.

19. The method according to claim 7, wherein the protective layer is a hard film formed on the pixel structure by a patterning process.

20. The method according to claim 8, wherein the protective layer is a hard film formed on the pixel structure by a patterning process.
